(19) United States
(12) Patent Application Publication
(10) Pub. No.: US 2014/0083502 A1
(43) Pub. Date: Mar. 27, 2014

(54) SOLAR CELL

(71) Applicant: INDUSTRIAL TECHNOLOGY RESEARCH INSTITUTE, Hsinchu (TW)

(72) Inventors: Der-Chin Wu, Tainan City (TW); Chen-Hsun Du, Taipei City (TW)

(73) Assignee: INDUSTRIAL TECHNOLOGY RESEARCH INSTITUTE, Hsinchu (TW)

(21) Appl. No.: 13/726,650

(22) Filed: Dec. 26, 2012

(30) Foreign Application Priority Data
Sep. 21, 2012 (TW) 101134764

(51) Int. Cl. H01L 31/0376; H01L 31/052

(52) U.S. Cl. CPC H01L 31/03762; H01L 31/0527
USPC 136/258; 136/252; 136/259

(57) ABSTRACT

Provided is a solar cell including a substrate of a first conductivity type, a first electrode, a dielectric layer, a region of a second conductivity type, and a second electrode. The substrate of the first conductivity type has a front surface and a back surface opposite to each other. The first electrode is disposed on the front surface. The dielectric layer has charges. The dielectric layer is disposed on the front surface and positioned at both sides of the first electrode. The region of the second conductivity type is disposed between the substrate of the first conductivity type and the first electrode, wherein the region of the second conductivity type is disposed only below the first electrode. The second electrode is disposed on the back surface.

### CROSS-REFERENCE TO RELATED APPLICATION

This application claims the priority benefit of Taiwan application serial no. 101134764, filed on Sep. 21, 2012. The entirety of the above-mentioned patent application is hereby incorporated by reference herein and made a part of this specification.

### TECHNICAL FIELD

The disclosure relates to a solar cell.

### BACKGROUND

The solar energy is an almost inexhaustible and substantially non-polluting resource. Facing issues of global warming and energy crisis, the solar energy is the solution that attracts the most attention. A solar cell is able to directly convert the solar energy into electric energy, and therefore currently it is a quite important research topic.

For example, a conventional solar cell may include an n-type silicon substrate and a p-type emitter formed on the n-type silicon substrate. Moreover, an anti-reflection layer may also be disposed on the p-type emitter so as to reduce light reflection. A back surface electric field layer may be formed below the n-type silicon substrate so as to reduce carrier recombination.

When light is incident on the solar cell, it first passes through the p-type emitter and is absorbed thereby. Electron-hole pairs are generated by the incident light. The electric field within a depletion region pulls electrons to the back surface, far away from the emitter region, so as to reduce the recombination in the emitter region and the surface of the wafer. In general we know the p-n junction is actually a good solar cell structure. However, the emitter consists of a heavily doped region with a depth of more than hundreds of nanometers into the silicon substrate, and the generated carriers cause a serious carrier recombination within such heavily doped region. It results in reduction of the output currents and voltages. Although the heavily doped emitter region plays a good role in separating the generated holes and electrons, it is also one of the key factors that limit the conversion efficiency. In view of this, a heterojunction with intrinsic thin layer (HIT) structure with an ultra-thin emitter design and interdigitated back contact (IBC) structure emerge as a result, wherein such two structures have a characteristic of high efficiency. Moreover, a passivated emitter and rear-locally diffused (PERL) structure is also a structure with a high efficiency. In recent years, the research and development of solar cell structures are established based on the above structures.

### SUMMARY

The present disclosure provides a solar cell with a high photoelectric conversion efficiency.

The present disclosure provides a solar cell including a substrate of a first conductivity type, a first electrode, a first dielectric layer, a region of a second conductivity type, and a second electrode. The substrate of the first conductivity type has a front surface and a back surface opposite to each other. The first electrode is disposed on the front surface. The dielectric layer having a first-type charge is disposed on the front surface and positioned at both sides of the first electrode. The region of the second conductivity type is disposed between the substrate of the first conductivity type and the first electrode, wherein the region of the second conductivity type is disposed only below the first electrode. The second electrode is disposed on the back surface.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a cross sectional view of a solar cell in accordance with the first embodiment.

FIG. 2 is a cross sectional view of a solar cell in accordance with the second embodiment.

FIG. 3 is a cross sectional view of a solar cell in accordance with the third embodiment.

FIG. 4 is a cross sectional view of a solar cell in accordance with the fourth embodiment.

FIG. 5 is a cross sectional view of a solar cell in accordance with the fifth embodiment.

FIG. 6A to FIG. 6D are cross sectional views of a process flow of a manufacturing method of a solar cell.

### DETAILED DESCRIPTION OF DISCLOSED EMBODIMENTS

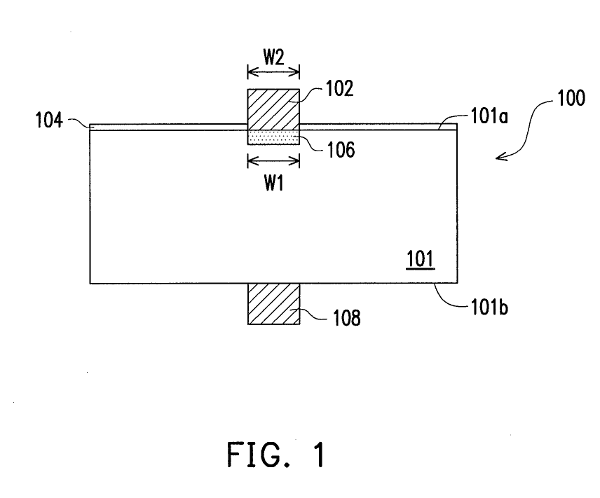

FIG. 1 is a cross sectional view of a solar cell in accordance with the first embodiment.

Referring to FIG. 1, a solar cell 100 includes a substrate 101 of a first conductivity type, a first electrode 102, a first dielectric layer 104, a region 106 of a second conductivity type, and a second electrode 108.

In the present embodiment and each of the following embodiments, an n-type silicon substrate will be illustrated as an example of the substrate 101 of the first conductivity type, and yet the present disclosure is not limited thereto. In other possible embodiments, the substrate 101 of the first conductivity type may be a p-type silicon substrate or any other suitable substrates.

The substrate 101 of the first conductivity type includes a front surface 101a and a back surface 101b opposite thereto. In FIG. 1, the front surface 101a and the back surface 101b are illustrated as flat surfaces, and yet the present disclosure is not limited thereto. In other possible embodiments, the front surface 101a may also include a surface texture structure so as to reduce surface reflectivity and extend the light passing path within the substrate 101 of the first conductivity type, resulting in more opportunities of the light being absorbed.

The first electrode 102 is disposed on the front surface 101a. A material of the first electrode 102 may include a metal such as silver or copper.

The first dielectric layer 104 is disposed on the front surface 101a and positioned at both sides of the first electrode 102. The first dielectric layer 104 has first type charges. The first-type charges may be positive charges or negative charges, which may be selected based on the conductivity type of the substrate 101 of the first conductivity type. Specifically, the first-type charges attract minority carriers within the substrate 101 of the first conductivity type. That is, if the substrate 101 of the first conductivity type is an n-type substrate, then the first-type charges are negative charges; if the substrate 101 of the first conductivity type is a p-type substrate, then the first-type charges are positive charges.

In the first embodiment, the first dielectric layer 104 includes, for example, Al₂O₃, which is a material with negative charges at silicon interface, and its charge density is greater than 10¹² q/cm⁻², or may even greater than 10¹³ q/cm⁻². The generated holes excited by incident light may be attracted by the negative charges and cluster near the front surface 101a to form an accumulation layer (not shown) with high hole concentration. The hole concentration of such accumulation layer is greater than a doping concentration of the original substrate 101 of the first conductivity type. Sometimes such accumulation layer is referred as an inversion layer in the present technical field. The inversion layer is advantageous to conduct hole current. Moreover, the first dielectric layer 104 with the first-type charges may repulse majority carriers within the substrate 101 of the first conductivity type and attract the minority carriers, and therefore it may serve as a surface passivation layer for suppressing a recombination of electron-hole pairs. In other embodiments, the first dielectric layer 104 may also include other materials, such as HfO₂. Alternatively, the first dielectric layer 104 may include a combination of Al₂O₃ and HfO₂. Furthermore, if the first-type charges are positive charges, the first dielectric layer 104 may include SiNx:H, SiO₂, Y₂O₃, La₂O₃, or a combination thereof.

The region 106 of the second conductivity type is disposed between the substrate 101 of the first conductivity type and the first electrode 102, and the region 106 of the second conductivity type is positioned only below the first electrode 102. If the first conductivity type is n-type, then the second conductivity type will be p-type; if the first conductivity type is p-type, then the second conductivity type will be n-type. As used in this specification, the description “the region 106 of the second conductivity type is positioned only below the first electrode 102” indicates that, within the concept of the present disclosure, the region 106 of the second conductivity type may not substantially extend horizontally to other positions from the position illustrated in FIG. 1. For example, it may not extend to the underneath of the first dielectric layer 104. That is, the region 106 of the second conductivity type and the first electrode 102 align in a vertical direction, and a width W1 of the region 106 of the second conductivity type is equal to a width W2 of the first electrode 102. However, it should be clarified herein that, when a solar cell is manufactured in reality, it is possible that the manufacturing process is carried out in a non-ideal way. Therefore, it is possible that the width W1 of the region 106 of the second conductivity type being slightly greater than the width W2 of the first electrode 102. Moreover, if necessary, a size of the region 106 of the second conductivity type may decrease in a horizontal direction, and the width W1 thereof being less than the width W2 of the first electrode 102 may be a possible type of embodiment.

In an embodiment, the region 106 of the second conductivity type is, for example, a heavily doped region of the second conductivity type formed in the substrate 101 of the first conductivity type. Note that, although the region 106 of the second conductivity is formed in the substrate 101 of the first conductivity type under this condition, such arrangement is still described as “the region 106 of the second conductivity type is disposed between the substrate 101 of the first conductivity type and the first electrode 102” in this specification. The region 106 of the second conductivity type includes, for example, a heavily doped region with p-type dopants (e.g. boron). The region 106 of the second conductivity type is an emitter of the solar cell 100, and a p-n junction between the emitter and the substrate 101 of the first conductivity type may separate electron-hole pairs, enabling the solar cell 100 to output electricity.

The solar cell 100 may also include a second electrode 108 disposed on the back surface 101b. A material of the second electrode 108 may include a metal, such as aluminium, copper, or silver.

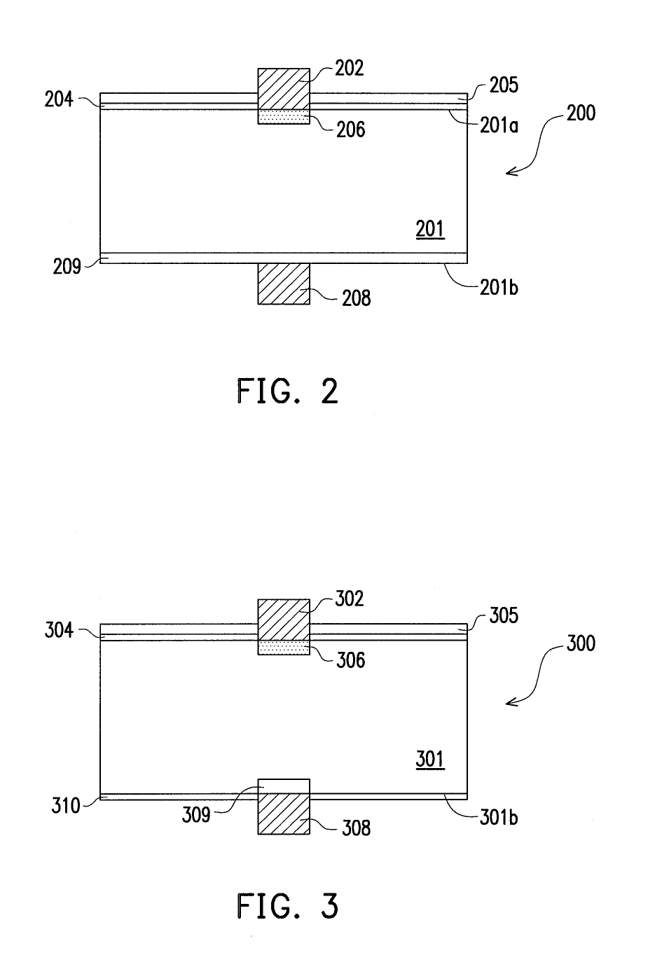

FIG. 2 is a cross sectional view of a solar cell in accordance with the second embodiment.

Referring to FIG. 2, a solar cell 200 includes a substrate 201 of a first conductivity type, a first electrode 202, a first dielectric layer 204, a region 206 of a second conductivity type, a second electrode 208, an anti-reflection layer 204, and a region 209 of the first conductivity type.

The substrate 201 of the first conductivity type, the first electrode 202, the first dielectric layer 204, the region 206 of the second conductivity type, and the second electrode 208 may be the same as the correspondents in the first embodiment, and thus will not be described herein.

The anti-reflection layer 205 is disposed on the first dielectric layer 204. The anti-reflection layer 205 may reduce light reflection at a front surface 201a, increasing the usage efficiency of the light. The material of the anti-reflection layer 205 is, for example, Si₃N₄, TiO₂, SiO₂, MgF₂, ZnO, etc.

The region 209 of the first conductivity type is, for example, a heavily doped region of the first conductivity type disposed on a back surface 201b of the substrate 201 of the first conductivity type. As compared to the substrate 201 of the first conductivity type, it has a higher doping concentration, which may repulse minority carriers so as to suppress a recombination of electron-hole pairs at the back surface 101b. In the present technical field, the region 209 of the first conductivity type is normally referred as a back surface field layer.

FIG. 3 is a cross sectional view of a solar cell in accordance with the third embodiment.

Referring to FIG. 3, a solar cell 300 includes a substrate 301 of a first conductivity type, a first electrode 302, a first dielectric layer 304, an anti-reflection layer 305, a region 306 of a second conductivity type, a second electrode 308, a region 309 of the first conductivity type, and a second dielectric layer 310.

The substrate 301 of the first conductivity type, the first electrode 302, the first dielectric layer 304, the anti-reflection layer 305, the region 306 of the second conductivity type, and the second electrode 308 may be the same as the correspondents in the second embodiment, and thus will not be described herein.

The region 309 of the first conductivity type is disposed between the substrate 301 of the first conductivity type and the second electrode 308, and is positioned only above the second electrode 308. The description “positioned only above the second electrode 308” has a meaning similar to “the region 106 of the second conductivity type is positioned only below the first electrode 102” as defined in the foregoing paragraph. That is, although the region 309 of the first conductivity type illustrated in FIG. 3 perfectly aligns with the second electrode 308 in a vertical direction, it is possible that the region 309 of the first conductivity type slightly extends along a horizontal direction, resulting a minor part of the region 309 of the first conductivity type being extending to the above of the second dielectric layer 310. Moreover, it is also possible that the region 309 of the first conductivity type decreasing in the horizontal direction, causing a width thereof being less than a width of the second electrode 308.

In the third embodiment, the region 309 of the first conductivity type is, for example, a heavily doped region formed in the substrate 301 of the first conductivity type. Note that, such arrangement is still described as “the region 309 of the first conductivity type is disposed between the substrate 301 of the first conductivity type and the second electrode 308” in this specification. In the embodiment of a n-type silicon substrate being the substrate 301 of the first conductivity type, the region 309 of the first conductivity type includes, for example, a heavily doped region with n-type dopants (e.g. phosphors).

The second dielectric layer 310 is disposed on the back surface 301b of the substrate 301 of the first conductivity type and positioned at both sides of the second electrode 308. The second dielectric layer 310 has second-type charges. The second-type charges may be positive charges or negative charges, which may be selected based on the conductivity type of the substrate 301 of the first conductivity type. Specifically, the second-type charges may repulse minority carriers in the substrate 301 of the first conductivity type. That is, if the first conductivity type is n-type, then the second-type charges are positive charges; if the first conductivity type is p-type, then the second-type charges are negative charges. In other words, in the third embodiment, the first-type charges of the first dielectric layer 304 are negative charges, and the second-type charges of the second dielectric layer 310 are positive charges. Of course, the present embodiment is not limited thereto; in other embodiments, the first-type charges may also be positive charges, and meanwhile the second-type charges may be negative charges. In the third embodiments, a material of the second dielectric layer 310 is, for example, SiNx:H, wherein SiNx:H may provide an effect of surface passivation and carrier recombination reduction. Furthermore, if the second-type charges are negative charges, the second dielectric layer 310 may include Al₂O₃, HfO₂, or a combination thereof.

In the third embodiment, a material of the anti-reflection layer 305 is, for example, SiNx:H. Since SiNx:H provides an anti-reflection effect, the anti-reflection layer 305 may also be an anti-reflection layer disposed on a front surface of a solar cell. In other types of embodiments, if the anti-reflection layer 305 has a multiple anti-reflection structures, another anti-reflection layer (not shown) may be deposited on the anti-reflection layer 305. Other than SiN, the material of the anti-reflection layer may also be Si₃N₄, TiO₂, SiO₂, MgF₂, and ZnO.

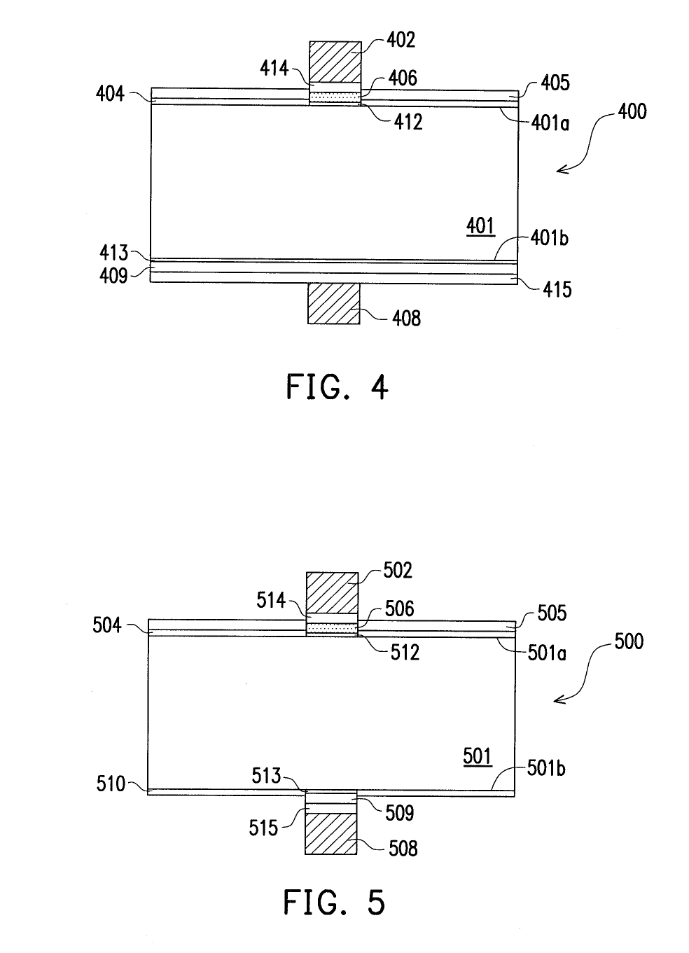

FIG. 4 is a cross sectional view of a solar cell in accordance with the fourth embodiment.

Referring to FIG. 4, a solar cell 400 includes a substrate 401 of a first conductivity type, a first electrode 402, a first dielectric layer 404, an anti-reflection layer 405, a region 406 of a second conductivity type, a second electrode 408, a region 409 of the first conductivity type, an intrinsic amorphous silicon layer 412, an intrinsic amorphous silicon layer 413, a transparent conducting layer 414, and a transparent conducting layer 415.

The substrate 401 of the first conductivity type, the first electrode 402, the first dielectric layer 404, the anti-reflection layer 405, and the second electrode 408 may be the same as the correspondents in the third embodiment, and thus will not be described herein.

In the fourth embodiment, the region 406 of the second conductivity type is a deposition layer formed on a front surface 401a of the substrate 401 of the first conductivity type, and its material is, for example, p-type doped amorphous silicon. The region 406 of the second conductivity type is disposed between the first electrode 402 and the substrate 401 of the first conductivity type, and is positioned only below the first electrode 402. To form the region 406 of the second conductivity type and the first electrode 402, an opening would normally be formed within the first dielectric layer 404 and the anti-reflection layer 405. Then, the region 406 of the second conductivity type and the first electrode 402 are sequentially formed to fill up the opening. Therefore, “the region 406 of the second conductivity type is positioned only below the first electrode 402” may refer to a situation that a width of the region 406 of the second conductivity type and a width of the first electrode 402 being substantially equal; additionally, it may refer to another situation that the width of the region 406 of the second conductivity type being less than the width of the first electrode 402.

In the fourth embodiment, the intrinsic amorphous silicon layer 412 may be disposed between the region 406 of the second conductivity type and the front surface 401a (i.e. between the region 406 and the substrate 410 of the first conductivity type), so that the region 406 of the second conductivity type, the intrinsic amorphous silicon layer 412, and the substrate 401 of the first conductivity type form a heterojunction with intrinsic thin layers (HIT). Furthermore, the transparent conducting layer 414 may be optionally disposed between the first electrode 402 and the region 406 of the second conductivity type. A material of the transparent conducting layer 414 is, for example, transparent conducting oxide, such as indium tin oxide (ITO).

In the fourth embodiment, the region 409 of the first conductivity type is a deposition layer formed on a back surface 401b of the substrate 401 of the first conductivity type, and its material is, for example, n-type doped amorphous silicon. The intrinsic amorphous silicon layer 413 may be disposed between the region 409 of the first conductivity type and the back surface 401b (i.e. between the region 409 and the substrate 401 of the first conductivity type). Furthermore, the transparent conducting layer 415 may be optionally disposed between the region 409 of the first conductivity type and the second electrode 408, and its material is, for example, the same as that of the transparent conducting layer 414.

FIG. 5 is a cross sectional view of a solar cell in accordance with the fifth embodiment.

Referring to FIG. 5, a solar cell 500 includes a substrate 501 of the first conductivity type, a first electrode 502, a first dielectric layer 504, an anti-reflection layer 505, a region 506 of a second conductivity type, a second electrode 508, a region of 509 the first conductivity type, a second dielectric layer 510, an intrinsic amorphous silicon layer 512, an intrinsic amorphous silicon layer 513, a transparent conducting layer 514, and a transparent conducting layer 515.

The substrate 501 of the first conductivity type, the first electrode 502, the first dielectric layer 504, the anti-reflection layer 505, the region 506 of the second conductivity type, the second electrode 508, the intrinsic amorphous silicon layer 512, and the transparent conducting layer 514 may be the same as the correspondents in the fourth embodiment, and thus will not be described herein.

The second dielectric layer 510 may be the same as the correspondent in the third embodiment.

In the fifth embodiment, the region 509 of the first conductivity type is a deposition layer disposed on a back surface 501b of the substrate 501 of the first conductivity type, and its material may be n-type doped amorphous silicon. The region 509 of the first conductivity type is disposed only above the second electrode 508. “The region 509 of the first conductivity type is disposed only above the second electrode 508” has a meaning similar to the definition of the region 406 of the second conductivity type. That is, it may refer to a situation that a width of the region 509 of the first conductivity type being substantially equal to that of the second electrode 508; it may also refer to a situation that the width of the region 509 of the first conductivity type being less than that of the second electrode 508.

The intrinsic amorphous silicon layer 513 may be disposed between the substrate 501 of the first conductivity type and the region 509 of the first conductivity type. The transparent conducting layer 515 may disposed between the region 509 of the first conductivity type and the second electrode 508. A material of the transparent conducting layer 515 is, for example, the same as that of the transparent conducting layer 514.

A variety of the embodiments are described hereinbefore in accordance with the concepts of the present disclosure. It is noted herein that the present disclosure is not limited to the above embodiments. Each of the elements described in each of the above embodiments may necessarily and properly be combined to form new types of embodiments. For example, the structure of the back surface in the second embodiment (including the second electrode 208 and the region 209 of the first conductivity type) may combine with the structure of the front surface in the fourth embodiment (including the first electrode 402, the first dielectric layer 404, the anti-reflection layer 405, the region 406 of the second conductivity type, the intrinsic amorphous silicon layer 412, and the transparent conducting layer 414) to form a new solar cell structure. Such structure and other possible structures all fall within the scope of the present disclosure.

### <Manufacturing Method>

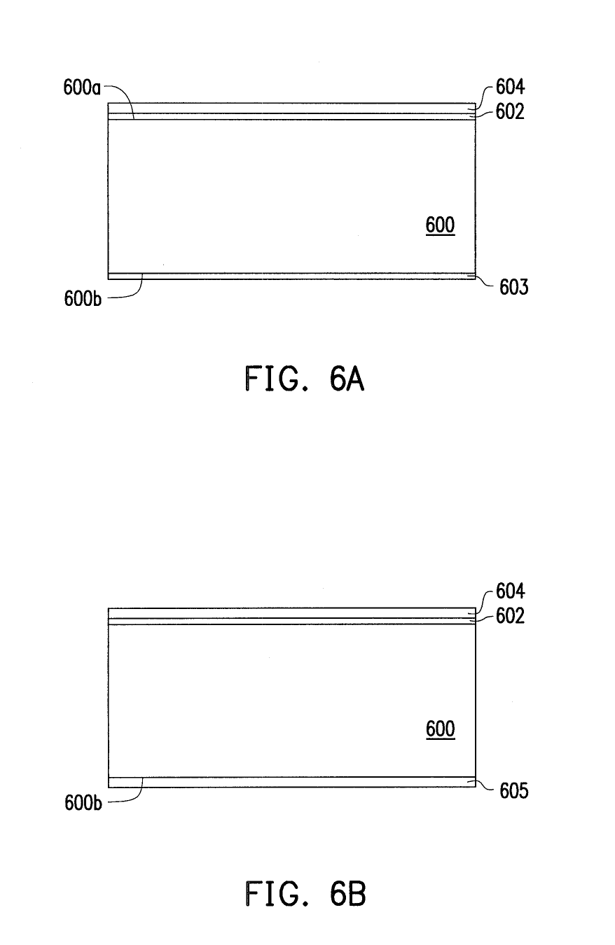

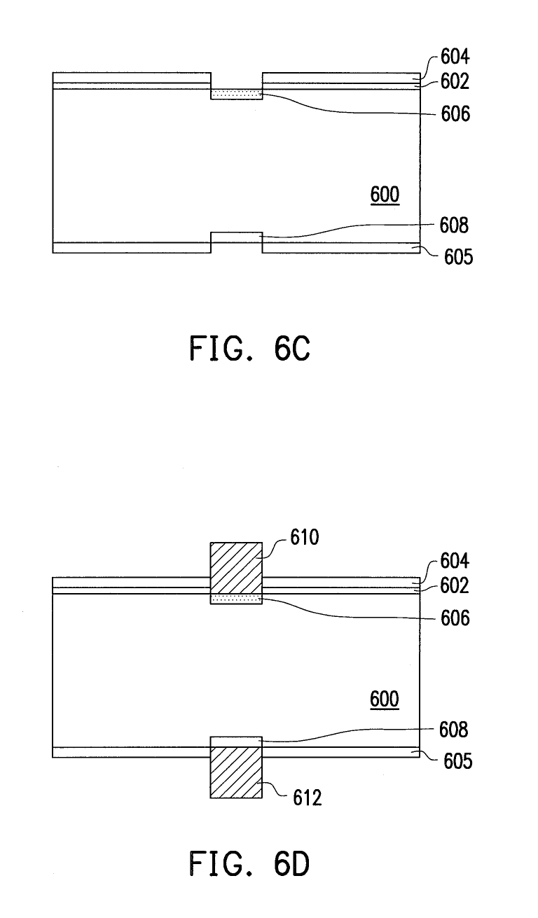

Referring to FIG. 6A to FIG. 6D hereinafter, a manufacturing method of a solar cell in accordance with an embodiment in the present disclosure will be explained.

Referring to FIG. 6A, first, as-cut n-type silicon wafer 600 is provided. Then, the n-type silicon wafer 600 is processed by a chemical etching treatment, wherein a front surface 600a thereof forms a micrometer-level pyramid surface texture structure, which is able to reduce the reflectivity of an incident light. The chemical etching treatment is, for example, a wet etching using alkaline etching solution. Moreover, a back surface 600b of the n-type silicon wafer 600 is processed into a flat surface by using acidic etching solution or alkaline etching solution, which is able to increase the reflectivity of the back surface and reduce the recombination rate of carriers on the surface.

Still referring to FIG. 6A, the n-type silicon wafer 600 is then washed to remove the etching residual. Then, the n-type silicon wafer 600 is disposed within an atomic layer deposition (ALD) reactor, and an aluminum oxide (Al₂O₃) thin film 602 and an aluminum oxide thin film 603 are grown on the front surface 600a and the back surface 600b respectively, wherein the thickness thereof are within a range of about 5 nm to 30 nm. Considering anti-reflection effect, the thickness of the aluminum-oxide thin film may be 10 nm in an embodiment. Then, a silicon nitride thin film 604 is deposited on the aluminum oxide thin film 602 by a plasma enhanced chemical vapor deposition (PECVD) method, wherein the thickness of the silicon nitride thin film 604 should be optimized based on reflectivity requirement. The aluminum oxide thin film 602 may be a surface passivation layer, while the aluminum oxide thin film 602 and the silicon nitride thin film 604 may both be anti-reflection layers.

Referring to FIG. 6B, the aluminum-oxide thin film 603 on the back surface 600b is removed, and the silicon nitride thin film 605 is deposited by the plasma enhanced chemical vapor deposition method. The method to remove the aluminum oxide thin film 603 is, for example, a wet etching process. The silicon nitride 605 may be the second dielectric layer in the above embodiments (such as the second dielectric layer 310 or the second dielectric layer 510).

Referring to FIG. 6C, by applying a laser chemical doping manufacturing process, an opening is opened for a front surface electrode to be formed within the aluminum oxide thin film 602 and the silicon nitride thin film 604 and another opening is opened for a back surface electrode to be formed within the silicon nitride thin film 605. Also, a p-type heavily doped region 606 and n-type heavily doped region 608 are formed within the n-type silicon wafer 600.

The laser chemical doping manufacturing process is a manufacturing process that combines laser beam local heating and solution doping, and it may achieve goals of electrode opening and chemical doping at the same time. In general, a boron doping is achieved by using boric acid solution, and a phosphorus doping is achieved by using phosphoric acid solution. That is, the p-type heavily doped region 606 is formed by adding boric acid with laser applied on the front surface 600a, and the n-type heavily doped region 608 is formed by adding phosphoric acid solution with laser applied on the back surface 600b.

Referring to FIG. 6D, after the p-type heavily doped region 606 and the n-type heavily doped region 608 are formed, the n-type silicon wafer will go through another washing manufacturing process again. Lastly, a front surface electrode 610 and a back surface electrode 612 are formed by a method of electro-depositing to complete the manufacture of the solar cell.

The solar cell manufactured by the above method may have a similar structure to that of the third embodiment. Moreover, the transparent conducting layer, the intrinsic amorphous silicon layer, and the doped amorphous silicon layer in the fourth embodiment and the fifth embodiment may be formed by, for example, the plasma enhanced chemical vapor deposition method. The present disclosure is definitely not limited to the above specific method. Methods known by a person having ordinary skill in the art may all be applied to form the solar cells in each embodiment in the present disclosure.

### <Simulated Experiment>

To further prove the effect of the present disclosure, a simulated experiment is performed by using a commercial simulation software. In the simulated experiment, the comparison example corresponds to a conventional structure; the experiment example 1 corresponds to the structure in the third embodiment; the experiment example 2 corresponds to the structure in the fourth embodiment; the experiment example 3 corresponds to the structure in the fifth embodiment; the experiment example 4 also corresponds to the structure in the fifth embodiment, but the thickness of the substrate of the first conductivity type reaches 400 μm. The doping concentration is 10¹⁵ cm⁻³, and the life time of minority carriers is 5 ms. The front surface of the cell includes a pyramid surface texture anti-reflection structure. The interface charge density between Al₂O₃ and the substrate is −10¹³ q/cm⁻²; the thickness of Al₂O₃ is 10 nm; the thickness of the anti-reflection layer SiN:H is 60 nm; the surface concentration of the p-type heavily doped region is 10²⁰ cm⁻³. Table 1 illustrates simulation results of short circuit current density (J_{SC}), open circuit voltage (V_{OC}), fill factor (FF), and photoelectric conversion efficiency (Eff.).

TABLE 1

| | J_{SC} | | | |
|---|---|---|---|---|
| | (mA/cm²) | V_{OC} (V) | FF | Eff.(%) |
| Comparison Example | 38.75 | 0.651 | 79.63 | 20.08 |
| Experiment Example 1 | 40.39 | 0.722 | 81.28 | 23.71 |
| Experiment Example 2 | 39.02 | 0.737 | 85.52 | 24.60 |
| Experiment Example 3 | 40.01 | 0.738 | 85.31 | 25.18 |
| Experiment Example 4 | 43.07 | 0.727 | 84.11 | 26.32 |

From Table 1, the solar cell in the present disclosures all have a higher photoelectric conversion efficiency than that in conventional solar cell, and their fundamental parameters including its short circuit current, open circuit voltage, fill factor are enhanced in overall.

To sum up the above, the above embodiments reduce the emitter region of a solar cell, which is disposed only below the front surface electrode, and an inversion layer is formed on the illuminated surface of the substrate by disposing the dielectric layer with charges. The hole concentration of such accumulation layer is greater than a doping concentration of the original substrate of the first conductivity type. Sometimes such accumulation layer is referred as an inversion layer in the present technical field. The inversion layer is advantageous to conduct hole current. Also, since there is no heavily-doped emitter at the illuminated portion, the carrier recombination is reduced, and the short circuit current and open circuit voltage both increase. Moreover, in some embodiments (such as the fourth embodiment and the fifth embodiment), the structures are combined with the heterojunction with intrinsic thin layer technique, which may further reduce carrier recombination at the junction layer so as to increase the open circuit voltage.

It should be pointed out that the open circuit voltage of the solar cell in the above embodiments increases as the doping concentration of the silicon substrate is reduced. That is, even the wafer with a high resistivity is used, the solar cell with a high efficiency can still be manufactured. Specifically, even the resistivity of the silicon substrate is above 5 Ωcm, the solar cell is still able to maintain a high efficiency, which is quite different from a conventional solar cell which optimized resistivity of the silicon substrate only located between about 1 Ωcm and about 5 Ωcm.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A solar cell comprising:
a substrate of a first conductivity type having a front surface and a back surface opposite to each other;
a first electrode disposed on the front surface;
a first dielectric layer having a first-type charge, wherein the first dielectric layer is disposed on the front surface and positioned at both sides of the first electrode;
a region of a second conductivity type disposed between the substrate of the first conductivity type and the first electrode and positioned only below the first electrode; and
a second electrode disposed on the back surface.

2. The solar cell of claim 1, wherein when the substrate of the first conductivity type is a n-type substrate, the first-type charge is a negative charge, and wherein when the substrate of the first conductivity type is a p-type substrate, the first-type charge is a positive charge.

3. The solar cell of claim 1, wherein a charge density of the first dielectric layer is greater than 10¹² q/cm⁻².

4. The solar cell of claim 1, wherein when the first-type charge is a negative charge, the first dielectric layer comprises Al₂O₃, HfO₂, or a combination thereof, and wherein when the first-type charge is a positive charge, the first dielectric layer comprises SiNx:H, SiO₂, Y₂O₃, La₂O₃, or a combination thereof.

5. The solar cell of claim 1 further comprising an anti-reflection layer disposed on the first dielectric layer.

6. The solar cell of claim 1, wherein the region of the second conductivity type is a doped region disposed in the substrate of the first conductivity type.

7. The solar cell of claim 1, wherein the region of the second conductivity type is a deposition layer disposed on the substrate of the first conductivity type.

8. The solar cell of claim 7, wherein the region of the second conductivity type comprises doped amorphous silicon.

9. The solar cell of claim 7 further comprising an intrinsic amorphous silicon layer disposed between the region of the second conductivity type and the front surface.

10. The solar cell of claim 1 further comprising a transparent conducting layer disposed between the first electrode and the region of the second conductivity type.

11. The solar cell of claim 1 further comprising a region of the first conductivity type disposed between the substrate of the first conductivity type and the second electrode.

12. The solar cell of claim 11, wherein the region of the first conductivity type is disposed only above the second electrode, and wherein the solar cell further comprises:
a second dielectric layer having a second-type charge, wherein the second dielectric layer is disposed on the back surface and positioned at both sides of the second electrode.

13. The solar cell of claim 12, wherein when the first-type charge is a negative charge, the second-type charge is a positive charge; and wherein when the first-type charge is a positive charge, the second-type charge is a negative charge.

14. The solar cell of claim 12, wherein when the second-type charge is a positive charge, the second dielectric layer comprises SiNx:H, SiO₂, Y₂O₃, La₂O₃, or a combination thereof, and wherein when the second-type charge is a negative charge, the second dielectric layer comprises Al₂O₃, HfO₂, or a combination thereof.

15. The solar cell of claim 11, wherein the region of the first conductivity type is a heavily doped region disposed within the substrate of the first conductivity type.

16. The solar cell of claim 11, wherein the region of the first conductivity type is a deposition layer disposed on the substrate of the first conductivity type.

17. The solar cell of claim 16, wherein the region of the first conductivity type comprises doped amorphous silicon.

18. The solar cell of claim 16 further comprising an intrinsic amorphous silicon layer disposed between the region of the first conductivity type and the back surface.

19. The solar cell of claim 16 further comprising a transparent conducting layer disposed between the region of the first conductivity type and the second electrode.
